(19) United States
(12) Patent Application Publication
(10) Pub. No.: US 2012/0199761 A1
(43) Pub. Date: Aug. 9, 2012

(54) OPTICAL PICKUP DEVICE, OPTICAL DISK DEVICE, AND MANUFACTURING METHOD FOR THE SAME

(76) Inventors: Keita Takanashi, Oume-shi (JP); Noriyuki Hiramatsu, Ota-shi (JP)

(21) Appl. No.: 13/501,422

(22) PCT Filed: Jun. 13, 2011
(86) PCT No.: PCT/JP2011/063994

§ 371 Date: Apr. 11, 2012

(30) Foreign Application Priority Data
Jun. 16, 2010 (JP) 2010-137367

(51) Int. Cl. H01L 31/12; B01J 19/12; H01L 21/50

(52) U.S. Cl. 250/578.1; 438/25; 250/492.1; 257/E21.499

(57) ABSTRACT

Provided is an optical pickup device with which a short-circuit can be released from above and below. The optical pickup device (15) is provided with: a housing (15B) formed by ejecting a resin material in a prescribed shape; an actuator (15D) that is positioned on the top surface of the housing (15B) so as to hold an objective lens (17); a circuit board (15A) that is fixed to the main surface of the housing (15B); and a connector (15C) that is attached to the top surface of the circuit board (15A). A second short-circuit part (25) and a first short-circuit part (24) are disposed on the top surface and the bottom surface of the circuit board (15A), and a built-in light-emitting chip is protected from electrostatic discharge damage by shorting either one of the short-circuit parts.

This application is the national stage under 35 USC 371 of the International Application No. PCT/JP2011/063994, filed Jun. 13, 2011, which claims priority from Japanese Patent Application Number JP 2010-137367 filed on Jun. 16, 2010, the contents of which are incorporated herein by reference in its entirety.

### FIELD OF THE INVENTION

The present invention relates to an optical pickup device including a short circuit unit which prevents a light emitting chip from being damaged by static electricity. The present invention further relates to an optical disc device including an optical pickup device in such a configuration, and to a manufacturing method of the optical disc device.

### BACKGROUND OF THE INVENTION

A light emitting chip of an optical pickup to be used in an optical disc device may be degraded or damaged because of static electricity received from a worker or the like who does assembly in an assembly process of the optical pickup, or an assembly process of the optical disc device.

Thus, in order to protect a light emitting chip against static electricity in the assembly processes, a wiring pattern connected to the anode electrode of a light emitting chip, and another wiring pattern connected to the cathode electrode of the light emitting chip are drawn out to be connected via solder on a drawing-out board so that both electrodes are short-circuited with the light emitting chip being disconnected from a circuit.

During the assembly process of an optical pickup, adjustments, inspections and the like of the optical pickup are performed, such as adjustments of the luminescence intensity of a light emitting chip, adjustments of the skew of an objective lens driving mechanism, and positional adjustment with a photodetector. In order for the light emitting ship to emit light for the above adjustments and the like, solder on the wiring patterns connected via the solder on the drawing-out board needs to be removed to eliminate short circuit between both electrodes. On the other hand, after the adjustments and inspections of the optical pickup, the wiring patterns are connected to each other by soldering again and both electrodes are short-circuited for the purpose of protecting the light emitting chip.

In addition, even in the product assembly process after the assembly process of the optical pickup, the solder on the wiring patterns connected via the solder on the drawing-out board needs to be removed to eliminate short circuit between both electrodes in order for the light emitting chip to emit light for adjustments, inspections, and the like on products.

On the other hand, after the adjustments and the inspections, the wiring patterns are connected to each other by soldering and both electrodes are short-circuited for the purpose of protecting the light emitting chip. Furthermore, in the final process, after the drawing-out board is connected to a circuit board on which a circuit for driving the optical disc device is mounted, the solder on the wiring on the drawing-out board need to be removed to eliminate short circuit between both electrodes in order for the light emitting chip to emit light.

As described above, it is necessary to repeat soldering and desoldering of the wiring on the drawing-out board in the assembly process of the optical pickup as well as the assembly process of the optical disc device.

As the soldering and desoldering of the wiring on the board are repeated multiple times, the board or wiring may be peeled off, and the wiring becomes thinner. The following proposals have been made in order to solve the above problem.

Referring to Patent Document 1, a technique is disclosed in which multiple connection areas for soldering (short circuit portions) are provided to lead conductors along their longitudinal direction in order to prevent a short circuit by soldering. By using the above technique, even when a lead conductor is peeled off at one connection area because of soldering and desoldering, subsequent soldering and desoldering can be performed at another connection area, and thereby a problem accompanying the peeling-off can be mitigated.

Furthermore, referring to Patent Document 2, means other than solder is used as a short circuit portion for short-circuiting the patterns temporarily in order to prevent electrostatic discharge damage. Specifically, referring to FIG. 4 and explanation thereof in Patent Document 2, patterned electric conductors on the board are short-circuited by using a clip 26. Furthermore, referring to FIG. 8B and explanation thereof in Patent Document 2, a short wire is used as the above-mentioned short-circuiting means. The process of soldering and desoldering can be eliminated by using these means disclosed in Patent Document 2.
Japanese Patent Application Publication 2005-216436
Japanese Patent Application Publication 2003-228866

### SUMMARY OF THE INVENTION

Since the optical pickup device itself does not include a protective resistance, the optical pickup device is shipped with the electrodes of the light emitting chip being short-circuited at the short circuit portion. The short circuit of the optical pickup device is eliminated after the optical pickup device is incorporated in the optical disc device.

However, conventionally, for the purpose of reducing the device in size, the above-mentioned short circuit portion is disposed only on the upper surface of the board provided in the optical pickup device.

On the other hand, a casing of the optical disc device, in which the optical pickup device is incorporated, is provided with an opening for eliminating short circuit by soldering.

In the case where the short circuit portion of the optical pickup device is exposed to the outside of the opening of the casing of the optical disc device, desoldering can be easily performed by inserting a soldering iron into the casing through the opening and bringing the soldering iron into contact with the short circuit portion. However, in the case where the short circuit portion of the optical pickup device is not exposed to the outside of the opening of the casing, there is a problem that it is difficult to bring the soldering iron into contact with the short circuit portion from the outside.

The present invention has been made in view of such a problem, and it is an object of the invention to provide an optical pickup device, an optical disc device, and a manufacturing method for the optical disc device that allow a short circuit to be eliminated from both upper and lower sides.

An optical pickup device of the present invention includes: a housing; a light emitting chip housed in the housing and configured to emit a laser beam; a circuit board which is fixed to the housing, and on which wiring connected to electrodes of the light emitting chip is formed, the circuit board having a first principal surface facing the housing, and a second principal surface opposed to the first principal surface; and a short circuit portion configured to allow the wiring connected to the electrodes of the light emitting chip to be short-circuited on the circuit board, wherein the short circuit portion has a first short circuit portion provided in the first principal surface of the circuit board, and a second short circuit portion provided in the second principal surface of the circuit board, in an area outside an outer periphery of the housing.

An optical disc device of the present invention, configured to emit a laser beam to an information recording medium and detect the laser beam reflected by the information recording medium, includes: a case; and the optical pickup device according to any one of claims 1 to 6, the optical pickup being movably housed inside the case, wherein any one of the first short circuit portion and the second short circuit portion of the optical pickup device is exposed to an outside of the case through an opening provided in the case.

One aspect of the present invention is a method of manufacturing an optical disc device configured to emit a laser beam to an information recording medium and detect the laser beam reflected by the information recording medium, the method of manufacturing comprising the steps of: preparing an optical pickup device which includes: a housing, a light emitting chip housed in the housing and configured to emit a laser beam, a circuit board which is fixed to the housing, and on which wiring connected to electrodes of the light emitting chip is formed, the circuit board having a first principal surface facing the housing, and a second principal surface opposed to the first principal surface, and a short circuit portion configured to allow the wiring connected to the electrodes of the light emitting chip to be short-circuited on the circuit board, wherein the short circuit portion has a first short circuit portion provided in the first principal surface of the circuit board, and a second short circuit portion provided in the second principal surface of the circuit board, in an area outside an outer periphery of the housing; short-circuiting the electrodes of the light emitting chip by short-circuiting the wiring at the first short circuit portion or the second short circuit portion of the optical pickup device; incorporating the optical pickup in a housing of the optical disc, and exposing the first short circuit portion or the second short circuit portion of the optical pickup device to an outside through an opening provided in one principal surface or another principal surface of the housing; and eliminating the short circuit at the first short circuit portion or the second short circuit portion.

According to the optical pickup device of the present invention, the first short circuit portion and the second short circuit portion are disposed on both principal surfaces of the projecting region on the circuit board fixed to the housing, the projecting region projecting to the outside from the housing. The electrodes of the built-in light emitting chips are short-circuited by short-circuiting any one of the first short circuit portion and the second short circuit portion, and thus electrostatic discharge damage of the light emitting chips is prevented. Even after the optical pickup device is incorporated in a set with severe space limitations, a short circuit at a short circuit portion can be eliminated from ether an upper side or a lower side of the optical pickup device.

According to the optical disc device of the present invention, both of the lower surface and upper surface of the built-in optical pickup device are provided with the short circuit portions, and thus regardless of whether an opening is provided to the upper surface of the case or the lower surface of the case, the first short circuit portion or the second short circuit portion of the optical pickup device can be exposed through the opening. Therefore, the solder bonded at the first short circuit portion or the second short circuit portion can be melted so as to eliminate the short-circuit by inserting a soldering iron into the inside through the opening of the case.

In addition, the optical pickup device of the present invention can be applied to an optical disc device of a type in which an opening is provided in the lower surface of the case, and to an optical disc device of a type in which an opening is provided in the upper surface of the case. Therefore, there is no need to individually design and prepare optical pickup devices in accordance with the above-mentioned types, which in turn reduces costs for parts and expense for part management of parts which are needed for an optical disc device.

### BRIEF DESCRIPTION OF THE DRAWINGS

FIG. 1 shows views of an optical pickup device of the present invention; FIG. 1A is a plan view from above of the optical pickup device; FIG. 1B is a plan view from below of the optical pickup device; and FIG. 1C is a cross-sectional view of the optical pickup device.

FIG. 2 shows views of a laser device incorporated in the optical pickup device of the present invention; FIG. 2A is a cross-sectional view of the laser device; and FIG. 2B is a diagram illustrating how light emitting chips are mounted.

FIG. 3 shows views of the optical pickup device of the present invention; FIG. 3A is a cross-sectional view of the optical pickup device; FIG. 3B is a view from above of a projecting region of a circuit board; and FIG. 3C is a perspective view from above of the projecting portion.

FIG. 4 shows views of another embodiment of a short circuit portion which is provided in the optical pickup device; FIG. 4A is a plan view illustrating another embodiment of a second short circuit portion; and FIG. 4B is a plan view illustrating another embodiment of a first short circuit portion.

FIG. 5 shows views of the optical disc device of the present invention; FIG. 5A is a cross-sectional view of the optical disc device; FIG. 5B is a view from above of the optical disc device; and FIG. 5C is a cross-sectional view of another optical disc device.

FIG. 6 shows views of an optical disc device in another configuration of the present invention; FIG. 6A is a cross-sectional view of the optical disc device; FIG. 6B is a view from below of the optical disc device; and FIG. 6C is a cross-sectional view of another optical disc device.

FIG. 7 is a cross-sectional view of another configuration of a short circuit area provided in the optical pickup device of the present invention.

FIG. 8 is a flowchart illustrating a manufacturing method of the optical disc device of the present invention.

### DETAILED DESCRIPTION OF THE INVENTION

### First Embodiment

### Configuration of Optical Pickup Device

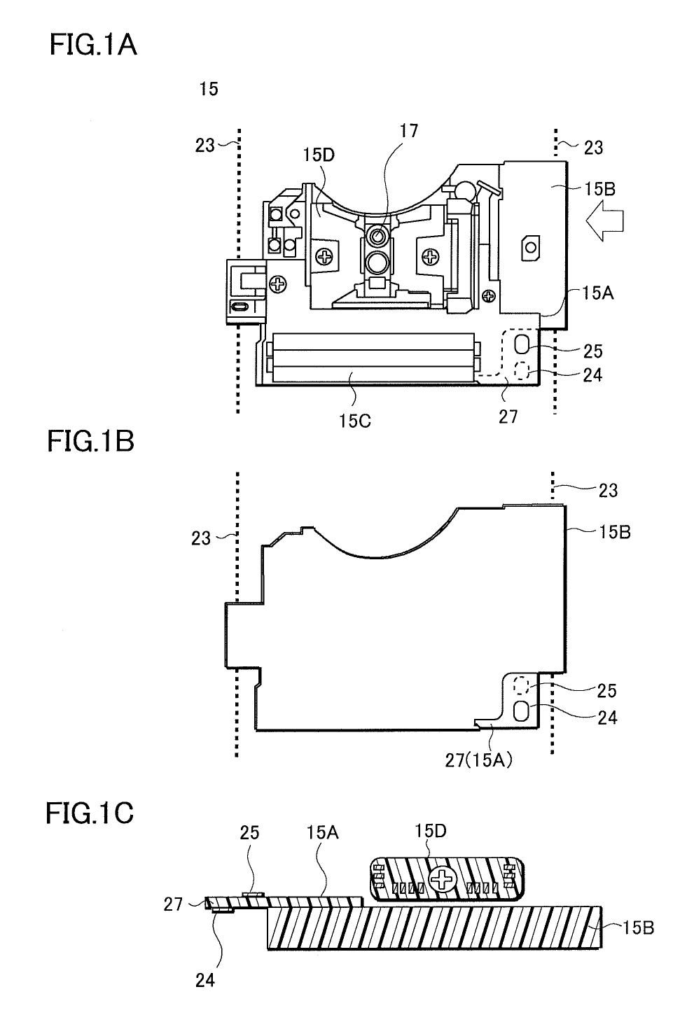

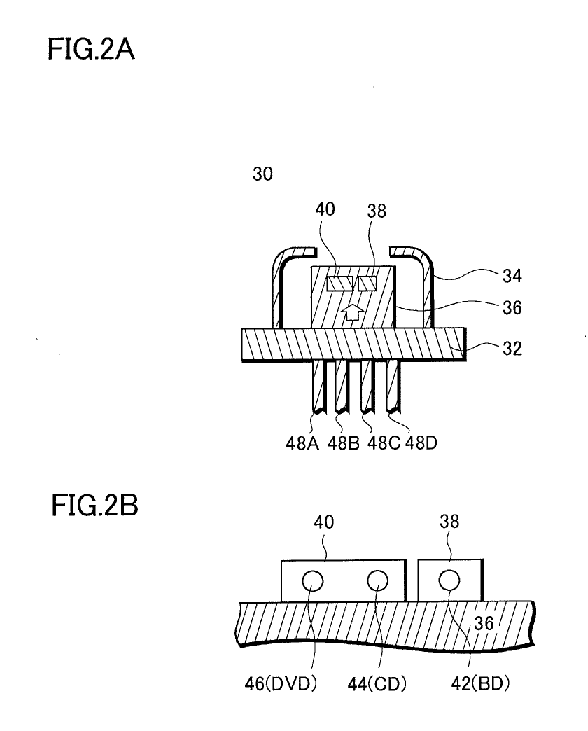

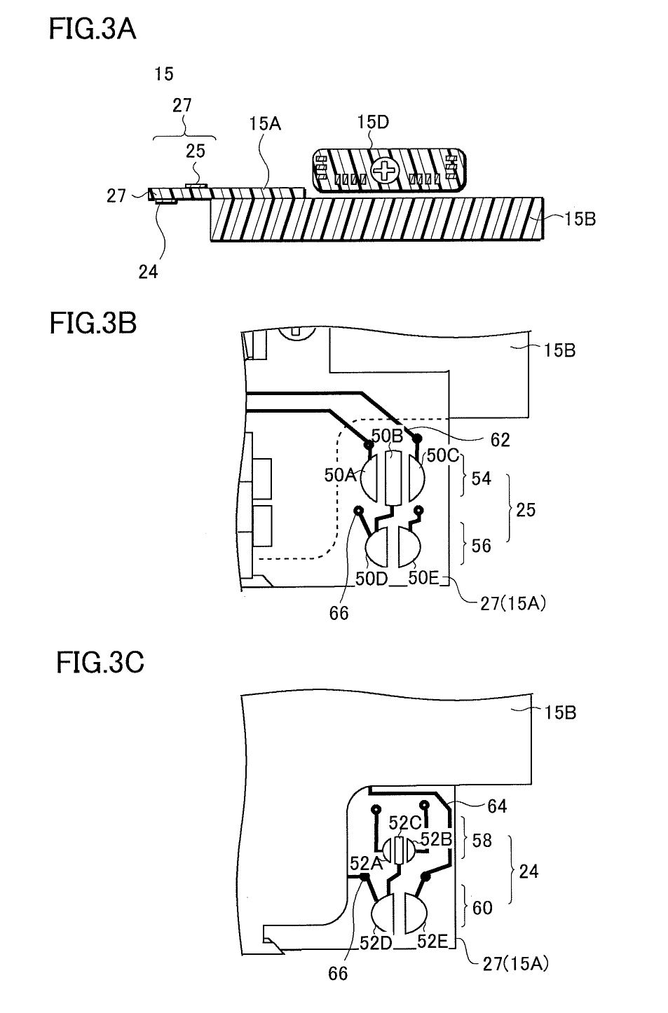

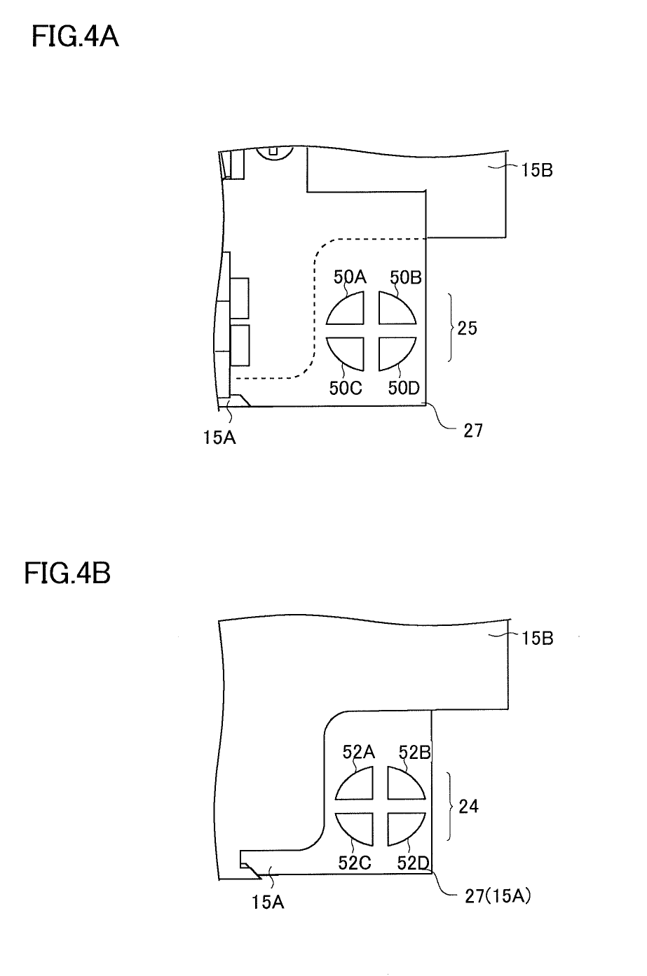

The configuration of an optical pickup device of the present embodiment is described with reference to FIGS. 1 to 4. FIG. 1 shows views of an optical pickup device 15; FIG. 2 shows views of a laser device which is incorporated in the optical pickup device; and FIGS. 3 and 4 are views of a short circuit portion which is an essential portion of the present embodiment.

First, the optical pickup device 15 is described with reference to FIG. 1. FIG. 1A is a plan view from above of the optical pickup device 15; FIG. 1B is a perspective view from above of the optical pickup device; and FIG. 1C is a side view (when viewed in the direction indicated by the arrow in FIG. 1A) of the optical pickup device. In the components of FIG. 1A, the front side of the drawing is referred to as a front surface, and the back side of the drawing is referred to as a back surface.

The optical pickup device 15 focuses a laser beam compliant with BD (Blu-ray Disc), DVD (Digital Versatile Disc), or CD (Compact Disc) onto an information recording surface of an information recording medium via objective lens 17, and converts reflection light from the information-recording surface into an electric signal via a light-receiving chip. The optical pickup device 15 includes a light emitting chip for BD, and a light emitting chip for DVD and CD. Here, the optical pickup device 15 is not necessarily compatible with those three types of laser beams, and may be compatible with two types of laser beams, or one type of laser beam. Each light emitting chip may be incorporated in the optical pickup device 15 dedicated only for reproduction, or may be incorporated in the optical pickup device 15 for performing reproduction and recording.

The specific configuration of the optical pickup device 15 includes a housing 15B obtained by injection-molding a resin material (or Mg alloy) into a predetermined shape; a circuit board 15A fixed to the surface of the housing 15B; an actuator 15D which holds the objective lens 17 located on the upper surface of the housing 15B, at least part of the actuator 15D being disposed on the surface of the circuit board 15A; a connector 15C exposed from the periphery of the actuator 15D, the connector 15C being fixed to the circuit board 15A on the surface of the circuit board 15A; and various optical devices incorporated in the housing 15B.

The housing 15B herein is formed by injection-molding a resin material into a predetermined shape. Specific description is given. Although the housing 15B has various two-dimensional outside shapes, but has a substantially rectangular shape. The longer side is formed in a curvy shape. Alternatively, the outside shape is a hexagon or the like which is formed by cutting an octagon in the center, and one longer side (the upper side in FIG. 1A) of the hexagon is formed in a curvy shape. The curvy shape is substantially the same as the outside shape of a turntable on which an optical disc is fixed. The bottom surface has this outside shape, and the side wall is provided along the front side to the back side of the drawing. Thus, a BOX shaped area formed by the wall side and the bottom surface is located on the back side of the drawing. As described later, the area is intricately provided with partitioning walls and projecting pieces integrally with the housing so as to dispose in the area a laser device, a light reflex or light transmission means such as a mirror, and a motor or the like for fine adjustment. On the other hand, the back side of the housing base, which can be viewed in FIG. 1A, is provided with projecting pieces, screw stop holes, and the like so that the actuator 15D and the circuit board 15A can be fixed on the back side. The bottom surface, the side wall, the partitioning walls, and the projecting pieces do not have the same thickness, but have an approximately 1 mm thickness.

The both right and left ends of the housing 15B is provided with holding mechanisms for a shaft including a first holding mechanism including a through-hole to allow a supporting axle 23 penetrate therethrough, and a second holding mechanism in a U shape to hold a supporting shank. Generally, holding is achieved by three-point holding, and two of the first holding mechanism is provided on the right or left, and the second holding mechanism is provided on the left or right. The optical pickup device 15 moves up and down on the drawing along the supporting axle 23 (dotted line) because of for the three-point holding.

The circuit board 15A is a board made of a resin, for example, a printed board, in which wiring is formed in the upper surface and the lower surface, and is fixed to the back side of the bottom surface of the housing 15B via fixing means such as a screw or an adhesive. The wiring formed in the principal surface of the circuit board 15A, is electrically connected to the light emitting chips and/or the light-receiving devices which are built in the housing 15B. As illustrated in FIG. 1A, two dimensional shape of the circuit board 15A is formed as a U shape in consideration of disposition of the actuator 15D. Specifically, the two dimensional shape includes three portions: two projecting portions fixed with a screw respectively located on the right and left of an opening portion, and a U-shaped bottom portion connecting the projecting portions. The opening portion has a size to allow the actuator 15D to disposed so that the longer side of the bottom portion is set to be slightly longer than the longer side of the actuator or the connector, and the width is set to be slightly longer than the width of the connector. Although the connector is disposed on the bottom portion, the bottom portion still has a connector-non-mounting region, around the connector, where adjustment parts such as wiring, a variable resistance, and a variable capacitor, electrodes or terminals are disposed.

The connector 15C is connected to an optical device built in the housing 15B, particularly an electric component such as a semiconductor device via the wiring formed in the circuit board 15A. The connector 15C serves as an external connection terminal of the optical pickup device 15.

Referring to FIGS. 1B and 1C, part of the circuit board 15A is formed as a projecting region 27 which projects partially from the outer periphery of the housing 15B in the present embodiment. The upper surface and the rear surface of the projecting region 27 are provided with short circuit portions (a first short circuit portion 24 and a second short circuit portion 25) for short-circuiting the electrodes of the built-in light emitting chips. The detail is described with reference to FIGS. 3 and 4.

The configuration of a laser device 30 which is one of the optical devices incorporated in the above-described optical pickup device 15 is described with reference to FIG. 2. FIG. 2A is a cross-sectional view of the laser device 30; and FIG. 2B is a diagram illustrating how light emitting chips are mounted. Here, FIG. 2B is a schematic view of the laser device 30 in FIG. 2A when viewed from an eye point indicated by the arrow in FIG. 2A, i.e. from below, and illustrates the configuration in which the light emitting chips are mounted. The illustrated three light sources emit light from the front side toward the back side in the drawing, and the light sources are located on the back side of the drawing.

Referring to FIG. 2A, the laser device 30 is a CAN type package, and includes a substantially disc-shaped board 32; a plate-shaped stem 36 fixed to the upper surface of the board 32; two light emitting chips mounted on the stem 36 (a first light emitting chip 38, a second light emitting chip 40); a covering portion (can portion) 34 which covers these light emitting chips; and terminal portions 48A to 48D which are electrically connected to the light emitting chips to be drawn out to the outside.

The configuration is made such that the laser device 30 is of a CAN type herein, but may be of a lead frame type. When a lead frame type device is used as the laser device 30, each light emitting chip is placed on the upper surface of an island, and the electrodes of the light emitting chip is connected to a lead. The light emitting chips and the island are sealed with a resin

The laser device 30 emits a laser beam with a predetermined wavelength from the first light emitting chip 38 or the second light emitting chip 40 using the power supplied from the outside via the terminal portions 48A to 48D. The laser beam emitted to the outside through an opening provided above the covering portion (can) 34.

Referring to FIG. 2B, the first light emitting chip 38 and the second light emitting chip 40 are mounted on the principal surface of stem 36 with the light emitting chips being spaced by a predetermined distance.

The first light emitting chip 38 is a laser diode composed of a semiconductor material such as zinc selenide or gallium nitride, and is fixed to the upper surface of the stem 36 via conductive binding material such as conductive paste. The end surface (back side of the drawing) of the first light emitting chip 38 is provided with a first light source 42, which emits a first laser beam compliant with BD standard.

The second light emitting chip 40 is a laser diode composed of a semiconductor material such as gallium arsenide, and is fixed to the upper surface of the stem 36 via conductive binding material similarly to the first light emitting chip 38. The end surface of the second light emitting chip 40 is provided with two light sources (a second light source 46, a third light source 44). The second light source 46 emits a second laser beam compliant with DVD standard, and the third light source 44 emits a third laser beam compliant with CD standard.

Here, the first laser beam has a blue violet wavelength band of 400 nm to 420 nm; the second laser beam has a red wavelength band of 645 nm to 675 nm; and the third laser beam has an infrared wavelength of 765 nm to 805 nm.

Referring to FIGS. 2A and 2B, the light emitting chips containing the above-described light sources are connected to the terminal portions 48A to 48D. For example, the terminal portion 48A is connected to the anode electrode of the first light source 42; the terminal portion 48B is connected to the anode electrode of the second light source 46; the terminal portion 48C is connected to the anode electrode of the third light source 44; and the terminal portion 48D is connected to the cathode electrodes of the light sources in common.

The above-described terminal portions 48A to 48D are electrically connected to the wiring of the circuit board 15A illustrated in FIG. 1. Furthermore, the cathode electrode and the anode electrode of each light source illustrated in FIG. 2B are connected to each other by short-circuiting the first short circuit portion 24 or/and the second short circuit portion 25. Consequently, these light sources are protected from an overvoltage due to static electricity. Although all the light emitting chips are housed in one can package herein, the light emitting chip for BD, and the light emitting chips for DVD and CD, for example, may be housed in different packages.

The short circuit portion which is the characteristic of the present invention is described in detail with reference to FIG. 3. FIG. 3A is a cross-sectional view of the optical pickup device, illustrating the location where the first short circuit portion 24 and the second short circuit portion 25 are disposed; FIG. 3B is a plan view illustrating the second short circuit portion 25; and FIG. 3C is a perspective view from above of the first short circuit portion 24.

Referring to FIG. 3A, first, the circuit board 15A is fixed to the surface of the housing 15B. The principal surface of circuit board 15A has wiring formed thereon which electrically connects optical devices such as light emitting chips built in the housing 15B. In the present embodiment, a short circuit portion for temporarily short-circuiting the wiring patterns is disposed on both principal surfaces of the circuit board 15A. Short-circuiting the wiring patterns connected to the light emitting chips via a short circuit portion causes the both electrodes of the light emitting chips to have the same electric potential, thus electrostatic discharge damage of the light emitting chips is prevented. Although solder is used as a means to cause a short-circuit, conductive paste may be coated or a conductive applied to the wiring.

In the present embodiment, part of the circuit board 15A is formed as a projecting region 27 which projects from the outer periphery of the housing 15B. The lower surface of the projecting region 27 is provided with the first short circuit portion 24, and the upper surface of the projecting region 27 is provided with the second short circuit portion 25. The first short circuit portion 24 and the second short circuit portion 25 are connected to the electrodes of the light emitting chips built in the housing 15B via the wiring and through-holes that are provided in the circuit board 15A. Soldering any one of the first short circuit portion 24 and the second short circuit portion 25 to be short-circuited causes the electrodes of the light emitting chips to be short-circuited, and thus electrostatic discharge damage of the light emitting chips is prevented. Furthermore, the short circuit is removed by desoldering at the first short circuit portion 24 and the second short circuit portion 25.

Although it has been described that the circuit board is projected from the housing 15B, by referring to FIG. 1A, it can be described that the lower right corner of the housing 15B is cut off, and the circuit board is exposed therefrom.

The second short circuit portion 25 provided on the surface of the circuit board 15A is described with reference to FIG. 3B. The second short circuit portion 25 includes a first short circuit region 54 for short-circuiting the electrodes connected to the light emitting device which emits a laser beam for CD and DVD, and a second short circuit region 56 for short-circuiting the electrodes connected to the light emitting device which emits a laser beam for BD.

The first short circuit region 54 includes three pads, 50A, 50B and 50C, which form a circular shape as a whole. These pads are connected to the electrodes of the light emitting devices (light sources) via wiring 62 and the through-holes provided on the surface and the rear surface of the circuit board 15A. As an example, the pad 50A is connected to the anode electrode of the light emitting device for CD; the pad 50B is connected to the cathode electrodes of the light emitting devices for CD and DVD in common; and the pad 50C is connected to the anode electrode of the light emitting device for DVD. The pad 50B is connected to the ground potential. In order to short-circuit the first short circuit region 54, solder is welded thereto so that pads 50A to 50C included in the first short circuit region 54 are contacted to each other. On the other hand, in order to eliminate the short circuit of the first short circuit region 54, a soldering iron is brought into contact with the solder bonded to the pads 50A to 50C, and melted solder is removed from the pads 50A to 50C by suction of a pulto or the like. Here, four pads for the anodes and cathodes of two light emitting devices may be prepared and short-circuited.

The second short circuit region 56 includes a pad 50D and a pad 50E, which generally form a circular shape. The pad 50D is connected to, for example, the cathode electrode of the light emitting device which emits a laser beam for BD, and the pad 50E is connected to the anode electrode of the light emitting device which emits a laser beam for BD. The pad 50D and the pad 50B of the first short circuit region 54 are connected to a fixed potential. The manner to short-circuit and eliminate a short circuit is the same as the manner for the second short circuit region 56.

In the assembly process performed by workers, relevant short circuit portion is short-circuited in order to prevent breakage of the light emitting device due to static electricity, while in the process of making adjustments and inspection of laser beam, the relevant short circuit is eliminated. Like the present embodiment, a short circuit at only one short circuit region may be eliminated by disposing the first short circuit region 54 for DVD and CD, and the second short circuit portion 25 for BD separately on different regions. For example, when adjusting a laser beam for DVD and CD, only short circuit at the first short circuit region 54 is eliminated, and the second short circuit portion 25 for B remains short-circuited. In this manner, electrostatic discharge damage of the light emitting device for 13D is prevented in the process of adjusting a laser beam for DVD and CD. In the process of adjusting a laser beam for BD, the first short circuit region 54 remains short-circuited, and a short circuit at the second short circuit portion 25 is eliminated.

Referring to FIG. 3C, the rear surface of the projecting region 27 of the circuit board 15A is provided with the first short circuit portion 24. Similarly to the above-described second short circuit portion 25, the first short circuit portion 24 includes a first short circuit region 58 for DVD and CD, and a second circuit region 60 for BD. The first short circuit region 58 includes pads 52A to 52C; the pad 52A is connected to the anode electrode of the light emitting device for CD; the pad 52B is connected to the cathode electrodes of the light emitting devices for CD and DVD in common; and the pad 52C is connected to the anode electrode of the light emitting device for DVD. The second short circuit region 60 includes pads 52D and 52E; the pad 52D is connected to the cathode electrode of the light emitting device which emits a laser beam for BD; and the pad 52E is connected to the anode electrode of the light emitting device which emits a laser beam for BD.

The pads 52A to 52E included in the first short circuit portion 24 are connected to the pads 50A to 50E included in the second short circuit portion 26, respectively, via the through-holes and the wiring 62, 64 provided in the circuit board 15A. The manner to short-circuit and eliminate a short circuit at the first short circuit portion 24 is the same as the manner for the second short circuit region. In addition, connection topology between the pads and the light sources included in the first short circuit portion 24 is the same as that in the second short circuit portion 25.

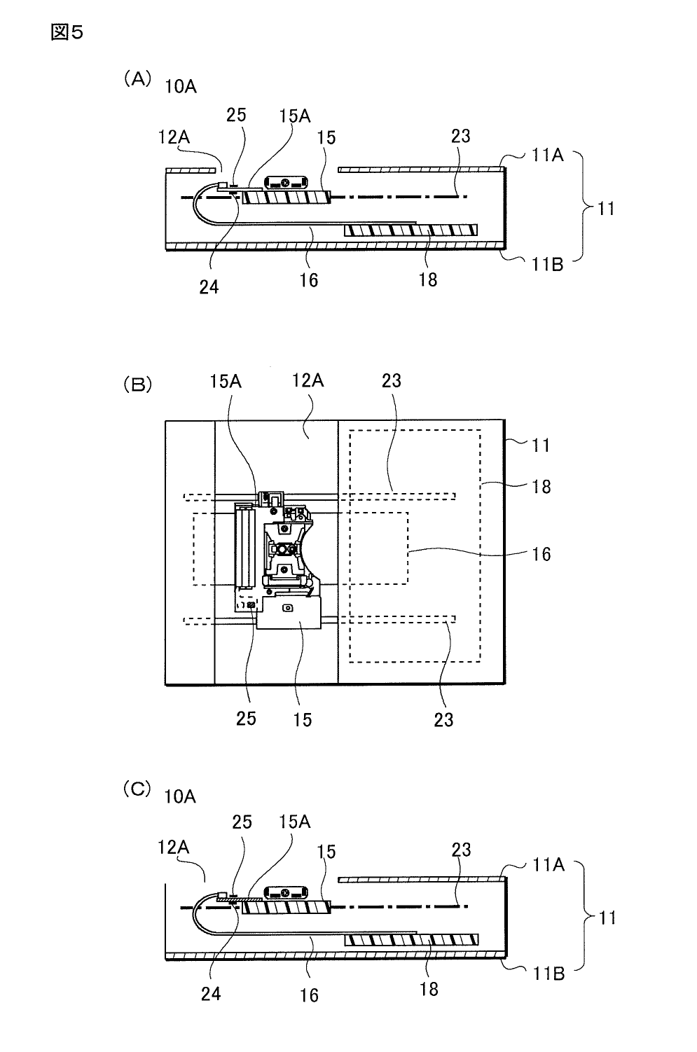

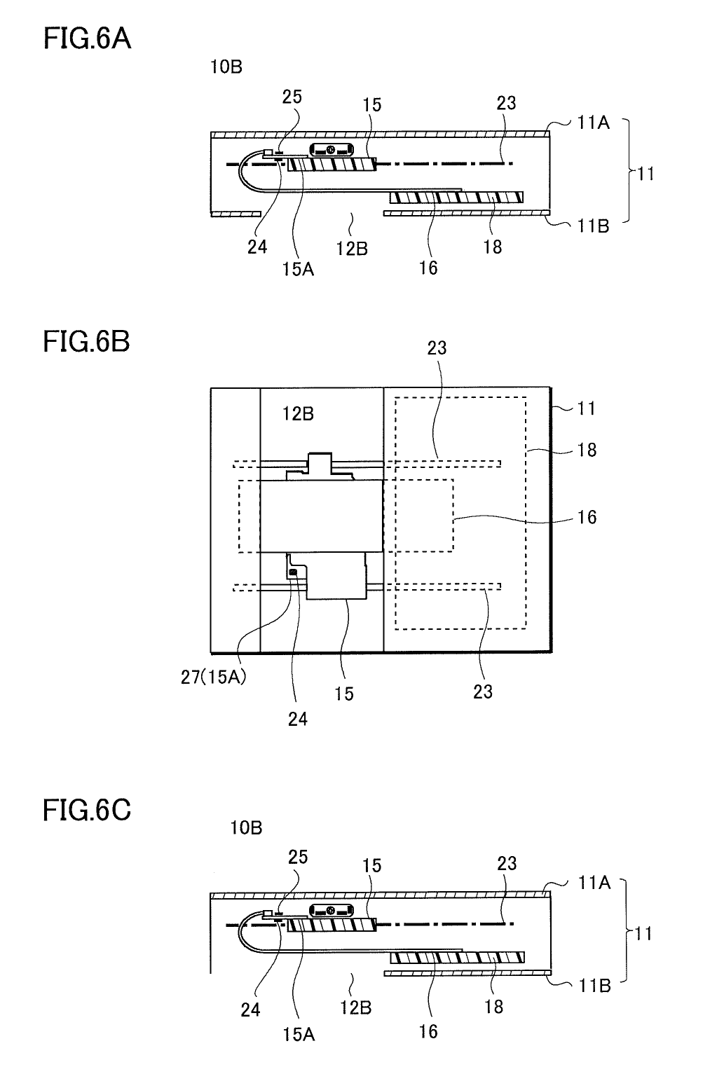

In the present embodiment, the rear surface of the circuit board 15A is provided with the first short circuit portion 24, and the upper surface of the circuit board 15A is provided with the second short circuit portion 25. The electrodes of the light emitting chips built in the housing 15B can be short-circuited by short-circuiting any one of the first short circuit portion 24 and the second short circuit portion 25. Consequently, when a short circuit is eliminated by desoldering, a soldering iron can be brought into contact with the solder in either direction from upper and lower the optical disc device so that the solder is removed. The detail of this is described later with reference to FIGS. 5 and 6.

In the present invention, part of the circuit board 15A is formed as the projecting region 27 which projects from the outer periphery of the housing 15B, and the rear surface of the projecting region 27 is provided with the first short circuit portion 24. Therefore, the rear surface of the projecting region 27 is covered by the housing 15B, and consequently a short circuit can be eliminated by applying a soldering iron to the solder bonded to the first short circuit portion 24 to remove the solder.

Here, the pads 50A to 50E included in the second short circuit portion 25 illustrated in FIG. 3B may be formed to be larger than the pads 52A to 52E included in the first short circuit portion 24 illustrated in FIG. 3C. At the second short circuit portion 25, short-circuiting and eliminating a short circuit may be performed a great number times in the process of manufacturing optical pickup device. That is to say, for the pads 50A to 50E included in the second short circuit portion 25, soldering and desoldering accompanied by heating are performed multiple times. In this case, when the pads 50A to 50C included in the second short circuit portion 25 are small, the pads may be degraded and damaged due to the heating when soldering and desoldering are performed. In the present embodiment, degradation of the pads 50A to 50C included in the second short circuit portion 25 is reduced by forming the pads 50A to 50C to be relatively large.

On the other hand, the first short circuit portion 24 provided in the rear surface of the circuit board 15A is a portion soldered when a manufactured optical pickup device is shipped, and desoldered after the optical pickup device is incorporated in an optical disc device. That is to say, the number of operations of soldering and desoldering for the first short circuit portion 24 is less than the number of operations of soldering and desoldering for the second short circuit portion 25. Therefore a damage due to the heating in the soldering and desoldering is relatively small, and thus the pads 52A to 52E included in the first short circuit portion 24 may be made relatively small.

In the present embodiment, the second short circuit portion 25 is disposed on the surface of the projecting region 27 of the circuit board 15A, however, the second short circuit portion 25 may be disposed on the upper surface of the circuit board 15A other than the projecting region 27. That is to say, the second short circuit portion 25 may be disposed on an inside area of the outer periphery of housing 15B, the inside area being on the upper surface of the circuit board 15A. Furthermore, the first short circuit portion 24 and the second short circuit portion 25 may overlap each other, or may not overlap each other.

Another embodiment of the above-described short circuit portion is described with reference to FIG. 4. FIG. 4A is a plan view illustrating the second short circuit portion 25 which is disposed on the upper surface of the circuit board 15A; and FIG. 4B is a plan view illustrating the first short circuit portion 24 which is disposed on the lower surface of the circuit board 15A. For the first short circuit portion 24 and the second short circuit portion 25 illustrated in FIG. 3, each short circuit portion includes multiple short circuit regions, however, each short circuit portion includes one short circuit region in the present embodiment.

Referring to FIG. 4A, the pads 50A to 50D that are concentrated on one region constitute the second short circuit portion 25. In addition, each of the pads 50A to 50D has a sector shape, and the pads 50A to 50D generally form a circular shape. The pad 50A is connected to the anode of the light emitting device for BD; the pad 50B is connected to the anode electrode of the light emitting device for DVD; and the pad 50C is connected to the anode electrode for CD. The pad 50D is the cathode electrodes of the devices as well as the ground potential.

When the second short circuit portion 25 is short-circuited, solder is welded to the pads 50A to 50D, and when a short circuit is eliminated from the second short circuit portion 25, a soldering iron is brought into contact with the solder and melted solder is removed.

The configuration of the first short circuit portion 24 illustrated in FIG. 4B is the same as the configuration of the second short circuit portion 25 illustrated in FIG. 4A, and the pads 52A-52D constitute the first short circuit portion 24.

Since the pads that constitute the second short circuit portion 25 are concentrated on one region, one time soldering allows the electrodes of the three light emitting devices to be short-circuited. Furthermore, one time desoldering allows the short circuits of the electrodes of the three light emitting devices to be eliminated. Consequently, time and effort needed for short-circuiting and eliminating a short circuit can be reduced.

### Second Embodiment

### Configuration of Optical Disk Device

The configuration of the optical disc device in which an optical pickup device having the above-described configuration is incorporated is described with reference to FIGS. 5 and 6. An optical disc device 10A illustrated in FIG. 5, and an optical disc device 10B illustrated in FIG. 6 are different with respect to the manner in which the optical pickup device 15 is exposed to the outside.

The optical disc device 10A is described with reference to FIG. 5. FIG. 5A is a cross-sectional view illustrating optical disc device 10A; and FIG. 5B is a plan view from above of the optical disc device 10A.

Referring to FIG. 5A, in the optical disc device 10A, a case 11 having an upper surface 11A and a lower surface 11B includes a main circuit board 18, a flexible printed circuit board 16, the optical pickup device 15, and the supporting axle 23 within the case 11.

The configuration of the optical pickup device 15 is the same as that described in the above embodiments, and the optical pickup device 15 is fixed to the inside of the case 11 via supporting axle 12a. The optical pickup device 15, while being used, moves to the right and left along the supporting axle 23.

The main circuit board 18 includes a circuit for performing recording or reproduction of signals on a disk, and a circuit for driving an optical disc device, and is fixed to the inside of the case 11. Furthermore, electric current used for emitting a laser beam from the light emitting chips built in the optical pickup device 15 is also supplied by the main circuit board 18.

The flexible printed circuit board 16 electrically connects the main circuit board 18 to the connectors of the optical pickup device 15. The flexible printed circuit board 16 has an excellent flexibility, and even when the optical pickup device is in motion, electrical connection between the main circuit board 18 and the optical pickup device 15 is maintained.

The case 11 is formed by processing a metal plate such as stainless steel into a housing form. The upper surface of the optical pickup device 15 is exposed through an opening 12A which is formed by opening a portion of the upper surface of the case 11. That is to say, the upper surface of the circuit board 15A, which is fixed to the housing, of the optical pickup device 15 is exposed to the outside through the opening 12A of the case 11.

Thus, referring to FIG. 5B, the second short circuit portion 25 provided on the upper surface of the optical pickup device 15 is exposed to the outside through the opening 12A. As described above, in the optical pickup device 15, the rear surface and the surface of the circuit board 15A are provided with the first short circuit portion 24 and the second short circuit portion 25, respectively. Here, the second short circuit portion 25 exposed to the outside through the opening 12A is used as short-circuiting means.

The optical pickup device 15 is shipped after being short-circuited to prevent electrostatic discharge damage, and after being incorporated in a set such as a disk reproduction device, the short circuit is eliminated. Here, the optical pickup device 15 is shipped in a state where the second short circuit portion 25 is soldered and short-circuited, and then is incorporated in the inside of the case 11,
Subsequently, the solder is removed and the short circuit is eliminated. When a short circuit is eliminated, a soldering iron is inserted into the inside of the case 11 through the opening 12A provided in the upper surface of the case 11, and is brought into contact with the solder bonded to the second short circuit portion 25 so that the solder is heated and melted, and thus is removed.

Referring to FIG. 5C, an optical disc device in another embodiment has the opening 12A which reaches the left end.

An optical disc device 10B in another embodiment is described with reference to FIG. 6. FIG. 6A is a cross-sectional view of the optical disc device 10B; and FIG. 6B is a plan view from above of the optical disc device 10B.

Referring to FIG. 6A, the basic configuration of the optical disc device 10B illustrated in FIG. 6A is similar to that of the optical disc device 1 OA illustrated in FIG. 5A, and the two configurations are different in the location of the opening. Specifically, in the optical disc device 10B illustrated in FIG. 6A, the opening 12B is formed by opening a portion of the lower surface 11 B of the case 11. Consequently, the lower surface of the optical pickup device 15 is exposed through the opening 12B. Most part of the circuit board 15A disposed on the upper surface of the optical pickup device 15 is not exposed through the opening 12B.

Referring to FIG. 6B, the undersurface of optical pickup device 15 and the projecting region 27 of the circuit board 15A are exposed through the opening 12B provided in the lower surface of the case 11. Here, short-circuiting is performed at the first short circuit portion 24 provided in the lower surface of the projecting region 27. That is to say, short-circuiting is not performed at the second short circuit portion 25, but is performed at the first short circuit portion 24 by soldering, and then the optical pickup device 15 is shipped with the above state. The optical pickup device 15 with short-circuited at the first short circuit portion 24 is incorporated in the inside of the case 11, and subsequently, a short circuit of the first short circuit portion 24 is eliminated.

When a short circuit at the first short circuit portion 24 is eliminated, referring to FIG. 6A a soldering iron is inserted into the inside of the case 11 through the opening 12B provided in the lower surface 11B of the case 11, and is brought into contact with the solder bonded to the first short circuit portion 24. Consequently, the solder welded to the first short circuit portion 24 is melted and removed so that a short circuit of the electrodes of the light emitting chips built in the optical pickup device 15 is eliminated.

Subsequently, electric current from the main circuit board 18 to the optical pickup device 15, adjustments and inspection of the optical pickup device 15 may be made inside the case 11 by supplying electric current from the main circuit board 18 to the optical pickup device 15, and emitting a predetermined laser beam from the light emitting chips built in the optical pickup device 15.

Referring to FIG. 6A, as described above, the optical pickup device 15 and the main circuit board 18 are connected to each other via the flexible printed circuit board 16. The flexible printed circuit board 16 is connected to the main circuit board 18 through the space below the optical pickup device 15 in order to allow deformation of the optical pickup device 15, which occurs when the optical pickup device moves to the right and left. Consequently, when the optical disc device 10B is viewed from below, most part of the lower surface of the optical pickup device 15 is covered by the flexible printed circuit board 16. For this reason, if no solution is applied, the first short circuit portion 24 provided in the lower surface of the circuit board 15A of the optical pickup device 15 is covered by the flexible printed circuit board 16, a short circuit may not be eliminated from the outside at the first short circuit portion 24 after the optical disc device 10B is assembled.

In order to prevent this, referring to FIG. 6B, the first short circuit portion 24 provided in the optical pickup device 16 is disposed at a location not overlapping the flexible printed circuit board 16. In this manner, even when the components constituting the optical disc device 10B are housed in the case 11, the first short circuit portion 24 is not covered by the flexible printed circuit board 16. Consequently, after the assembly of the optical disc device 10B is completed, a soldering iron is brought into contact with the first short circuit portion 24 from the outside of the case 11 so that a short circuit can be eliminated.

Referring to FIG. 6C, an optical disc device in another embodiment has the opening 12A which reaches the left end.

Here, in FIG. 5, the opening 12A is provided over the case 11. On the other hand, in FIG. 6, the opening 12B is provided under the case 11. However, the case may be provided with an opening over and under the case. Two openings over and under the case may be convenient for conducting work.

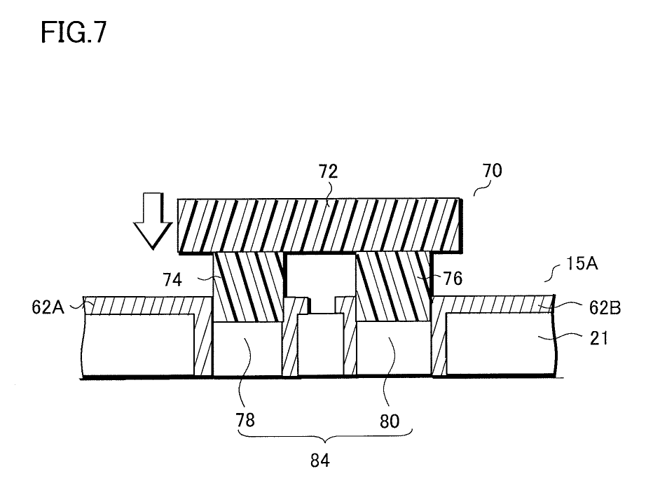

Another configuration of the short circuit portion is described with reference to the cross-sectional view in FIG. 7. Referring to FIG. 3B, the above-described second short circuit portion 25 includes the multiple pads 50A to 50E, and short-circuiting is performed by welding solder to the pads 50A to 50E. A short circuit portion 84 illustrated in FIG. 7 includes multiple through-holes, and short-circuiting and eliminating a short circuit are performed by inserting and extracting a short-circuit pin 70 into and from the through-holes.

Specifically, two patterns of wiring (wiring 62A and 62B) are disposed on the upper surface of a base material 21 of the circuit board 15A. The wiring 62A is connected to the anode electrode of the light emitting chip. The wiring 62B is connected to the cathode electrode of the light emitting chip. Here, the light emitting chip emits a laser beam compliant with BD, DVD, or CD standard.

The short circuit portion 84 which short-circuits the wiring 62A and the wiring 62B includes a through-hole 78 adjacent to the wiring 62A, and a through-hole 80 adjacent to the wiring 62B.

When the wiring is short-circuited at the short circuit portion 84, the projecting portions of the short circuit pin 70 are inserted in the through-holes of the short circuit portion 84. The short circuit pin 70 is composed of a conductive material such as a conductive resin, and includes two projecting portions 74, 76 that project downward from a plate-shaped board 72. Consequently, a short circuit is performed on the short circuit portion 84 via the short circuit pin 70 by inserting the two projecting portions 74, 76 of the short circuit pin 70 into the two through-holes 78, 80 of the short circuit portion 84. In addition, the short circuit is eliminated by drawing out the short circuit pin 70 from the short circuit portion 84.

The short circuit pin 70 may be inserted and extracted from above the circuit board 15A as illustrated in FIG. 7, or may be inserted and extracted from below.

### Third Embodiment

### Manufacturing Method of Optical Disk Device

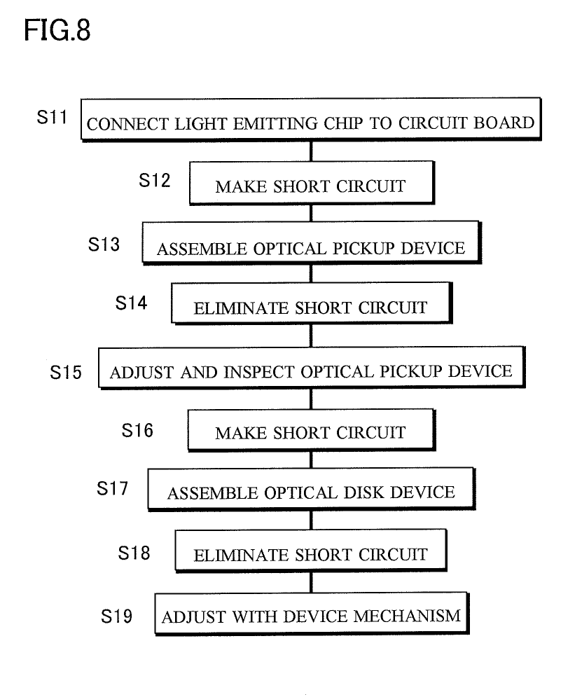

In the present embodiment, a method of manufacturing optical disc devices is described based on the flowchart in FIG. 8 with reference to the above-described figures.

A method of manufacturing optical disc devices of the present embodiment includes: Step S11 of connecting a light emitting chip and a circuit board; Step S13 of assembling an optical pickup device; Step S15 of making an inspection and a adjustment of the optical pickup device; Step S17 of assembling the optical disc device; and Step S19 of making an adjustment with a device mechanism.

In the method of manufacturing optical disc devices of the present embodiment, assembly is performed by workers, and thus wiring is short-circuited using the above-described short circuit pin in a process in which static electricity may be discharged from the workers. Accordingly, the electrodes of the light emitting chips built in the optical pickup device are short-circuited via the wiring and to have the same electric potential so that the light emitting chips are protected against electrostatic discharge damage.

On the other hand, when characteristic adjustment or an inspection of the optical pickup device is made, it is necessary to emit a laser beam from the light emitting chips built in the optical pickup device, thus the above short circuit is eliminated.

In the present embodiment two short circuit portions are provided in the optical pickup device, and are used for different situations depending on the structure of the optical disc device in which the optical pickup device is incorporated.

The method of manufacturing the optical disc device in the present embodiment is described in detail hereinafter.

In Step S11, the light emitting chips included in the optical pickup device and the circuit board are connected to each other. Specifically, referring to FIG. 1, the light emitting chips (not shown) included in the optical pickup device and the wiring disposed on the upper surface of the circuit board 15A are connected to each other. Here, for example, the light emitting chips which emit the laser beam of three standards (BD, DVD, and CD standard) are incorporated in the optical pickup device 15, and the wiring patterns formed on the upper surface and the lower surface of the circuit board 15A are connected to the electrodes of the light emitting chips. Specifically, as illustrated in FIG. 2, the light emitting chips are fixed to the housing of the optical pickup device as the packaged laser device 30 so that the wiring on the circuit board and the light emitting chip are connected via the terminal portions 48A to 48D of the laser device 30.

In addition, as illustrated in FIGS. 3B and 3C, the wiring patterns connected to the electrodes of the light emitting chips are connected to the short circuit portion. Specifically, the upper surface of the circuit board 15A is provided with the second short circuit portion 25 as illustrated in FIG. 3B, and the lower surface of the circuit board 15A is provided with the first short circuit portion 24 as illustrated in FIG. 3C. The first short circuit portion 24 and the second short circuit portion 25 are connected to each other via the through-hole 56 which penetrates through the circuit board 15A. Thus, the electrodes of the light emitting chips built in the optical pickup device 15 can be short-circuited by short-circuiting any one of the first short circuit portion 24 and the second short circuit portion 25.

Here, three light sources are built in the optical pickup device, however, the number of light sources to be built in may be one or two.

In Step S12, a short circuit is performed to protect the light emitting chips against electrostatic discharge damage. Specifically, soldering is performed on any one of the second short circuit portion 25 illustrated in FIG. 3B and the first short circuit portion 24 illustrated in FIG. 3C. Normally, soldering is performed on the optical pickup device 15 which is placed in a state as illustrated in FIG. 3A, thus performing a short-circuit on the second short circuit portion 25 provides improved workability. Since the pads included in the second short circuit portion 25 are formed to be greater than the pads included in the first short circuit portion 24, the second short circuit portion 25 is advantageously used to cause less degradation of the pads even after soldering and desoldering are performed on the pads multiple times. The second short circuit portion 25 illustrated here includes two short circuit regions (the first short circuit region 54 and second short circuit region 56), thus soldering needs to be performed twice.

When the second short circuit portion 25 or the first short circuit portion 24 having a form as illustrated in FIG. 4 is employed, a short circuit is performed on any one of the short circuit portions once.

In Step S13, assembly of the optical pickup device is performed with the light emitting chips built in the optical pickup device being short-circuited. Specifically, optical devices such as a lens constituting the optical pickup device, a package in which the light emitting chips are incorporated, and PDIC for receiving laser beams emitted from the light emitting chips are fixed to predetermined positions of the housing. The above work is performed by workers, thus static electricity may occur due to contact of the workers with the housing. However, as described above, the electrodes of the light emitting chips are short-circuited via the first short circuit portion 24 or the second short circuit portion 25 that are provided on the circuit board 15A, thus static electricity is not applied to the light emitting chips, and consequently the light emitting chips are protected against electrostatic discharge damage.

In Step S14, after the assembly of the optical disc device is completed, the short circuit is eliminated. Specifically, referring to FIG. 3B, a soldering iron is brought into contact with the solder bonded to the second short circuit portion 25 so that the solder is melted and removed. In the case where a short circuit is performed on the first short circuit portion 24 illustrated in FIG. 3C, a soldering iron is brought into contact with the solder bonded to the first short circuit portion 24 to remove the solder. In this manner, the cathode electrodes and anode electrodes of the light emitting chips that are built in the optical pickup device are made electrically independent.

In Step S15, adjustments and inspection of the optical pickup device are performed. Specifically, adjustments of the luminescence intensity of the optical pickup device, adjustments of the skew of the objective lens driving mechanism, and positional adjustment with a photodetector are made. Furthermore, an inspection of these adjustments is also made. In this step, a short circuit at the relevant short circuit portion is eliminated. Therefore, a predetermined voltage can be applied to the light emitting chips built in the optical pickup device 15. Consequently, in order to perform the adjustments and inspection in this present step, a laser beam is emitted from each light emitting chip.

After this step is completed, in order to protect the light emitting chips against static electricity received from the workers in the subsequent step of assembling the optical disc device, the wiring on the circuit board 15A is short-circuited at the first short circuit portion 24 or the second short circuit portion 26 (Step S16).

Here, a short circuit in this step is performed at any one of the first short circuit portion 24 and the second short circuit portion 26, and choice of a short circuit portion depends on the configuration of the optical pickup device. Specifically, as illustrated in FIG. 5, when the optical pickup device 15 is exposed through the opening 12A provided in the upper surface 11A of the optical disc device 10A, the second short circuit portion 25 disposed on the upper surface of the circuit board 15A is short-circuited. On the other hand, as illustrated in FIG. 6, when the optical pickup device 15 is exposed through the opening 12B provided in the lower surface 11B of the optical disc device 10B, the first short circuit portion 24 disposed on the lower surface of the circuit board 15A is short-circuited.

In Step S17, assembly of the optical disc device is performed with the above-mentioned short circuit. Specifically, for example, referring to FIG. 5, the optical pickup device 15 is housed in the case 11 with the optical pickup device 15 being supported by the supporting axle 23. The main circuit board 18 and the optical pickup device 15 are then connected via the flexible printed circuit board 16. Accordingly, a protection circuit incorporated in the main circuit board 18 and the light emitting chips that are built in the optical pickup device 15 are connected to each other, and thus a short circuit at a short circuit portion is not necessary.

After this step is completed, the short circuit is eliminated preceding the step of adjustments (Step S18). Specifically, referring to FIG. 5A, when the upper surface of the optical pickup device 15 is exposed through the opening 12A provided in the upper surface 11A of the case 11, a soldering iron is inserted into the inside of the case 11 through the opening 12A. The soldering iron is then brought into contact with to the solder bonded to the second short circuit portion 26 to heat and melt the solder so that the solder is removed and the short-circuit is eliminated. On the other hand, in the case illustrated in FIG. 6A, the soldering iron is inserted into the inside through the opening 12B provided in the lower surface 11B of the case 11. The soldering iron is brought into contact with the solder bonded to the first short circuit portion 24 provided in the lower surface of the circuit board 16A in the optical pickup device 15. Consequently, the solder bonded to the first short circuit portion 24 is melted and removed, thus a short circuit is eliminated.

In Step S17, adjustments with an optical disc device mechanism is made. Specifically, referring to FIG. 5A, positional adjustment of the optical pickup device 15 with respect to other components included in the optical disc device 10A is made. In this step, a voltage is applied to the light emitting chips built in the optical pickup device 15, and a laser beam is emitted from each light emitting chip. Positional relationship between the both is adjusted based on the laser beams emitted. Optical disk devices are manufactured in the above steps.

1-10. (canceled)

11. A method of manufacturing an optical pickup device configured to emit a laser beam to an information recording medium and detect the laser beam reflected by the information recording medium, the optical pickup device including:
a housing;
a first light emitting chip housed in the housing and configured to emit a first laser beam;
a second light emitting chip configured to emit a second laser beam whose wavelength is longer than a wavelength of the first light emitting chip;
a circuit board which is fixing to the housing, and on which a first wiring connected to electrodes of the first light emitting chip and a second wiring connected to electrodes of the second light emitting chip are formed, the circuit board including a first principal surface, and a second principal surface opposed to the first principal surface;
a first region which allows the first light emitting chip to be short-circuited on the circuit board by using the first wiring; and
a second region which allows the second light emitting chip to be short-circuited on the circuit board by using the second wiring,
the method comprising: adjusting the laser beam emitted from the second light emitting chip (or the first light emitting chip) with the first region (or the second region) being short-circuited.

12. A method of manufacturing an optical pickup device according to claim 11, wherein
the first light emitting chip emits a laser beam of BD standard, and
the second light emitting chip emits a laser beam of DVD standard or/and CD standard.

13. A method of manufacturing an optical pickup device according to claim 11, wherein
the first and second regions are arranged outside an outer periphery of the housing.

14. A method of manufacturing an optical pickup device according to claim 11, wherein
the first regions are formed on the first principal surface and the second principal surface of the circuit board,
the first light emitting chip is short-circuited by short-circuiting any one of the first regions,
the second regions are formed on the first principal surface and the second principal surface of the circuit board, and
the second light emitting chip is short-circuited by short-circuiting any one of the second regions.

15. A method of manufacturing an optical pickup device according to claim 11, wherein
the second region is formed to have a greater area in plan view than the first region is formed.

16. An optical pickup device comprising:
a housing;
a first light emitting chip housed in the housing and configured to emit a first laser beam;
a second light emitting chip housed in the housing and configured to emit a second laser beam whose wavelength is longer than a wavelength of the first light emitting chip;
a circuit board which is fixed to the housing, and on which a first wiring connected to electrodes of the first light emitting chip and a second wiring connected to electrodes of the second light emitting chip are formed, the circuit board including a first principal surface and a second principal surface opposed to the first principal surface;
a first region which allows the first light emitting chip to be short-circuited on the circuit board by using the first wiring; and
a second region which allows the second light emitting chip to be short-circuited on the circuit board by using the second wiring, wherein
the second region is formed to have a greater area in plan view than the first region is formed.

17. The optical pickup device according to claim 16, wherein
the first region has a first pad and a second pad which are connected to a first electrode and a second electrode, respectively, of the first light emitting chip,
the second region has a third pad and a fourth pad which are connected to a third electrode and a fourth electrode, respectively, of the second light emitting chip.

18. The optical pickup device according to claim 16, wherein
the second light emitting chip has a first light source configured to emit the second laser beam, and a second light source configured to emit a third laser beam whose wavelength is longer than the wavelength of the second laser beam,
the second region has a first pad connected to a first electrode of the first light source; a second pad connected to a first electrode of the second light source; and a third pad connected to a second electrode of the first light source and a second electrode of the second light source.

19. An optical pickup device, comprising:
a housing;
a first light emitting chip housed in the housing and having a first light source configured to emit a first laser beam;
a second light emitting chip housed in the housing and having a second light source configured to emit a second laser beam whose wavelength is longer than a wavelength of the first light emitting chip, and a third light source configured to emit a third laser beam whose wavelength is longer than the wavelength of the second light emitting chip,
a circuit board which is fixed to the housing, and on which a first wiring connected to electrodes of the first light emitting chip and a second wiring connected to electrodes of the second light emitting chip are formed, the circuit board including a first principal surface and a second principal surface opposed to the first principal surface;
a region in which the first light emitting chip and the second light emitting chip are short-circuited on the circuit board by using the first wiring and the second wiring, wherein
the region has a first pad connected to an anode electrode of the first light source, a second pad connected to an anode electrode of the second light source, a third pad connected to an anode electrode of the third light source, and a fourth pad connected to cathode electrodes of the first light source, the second light source, and the third light source.

20. The optical pickup device according to claim 19, wherein
the first pad, the second pad, the third pad, and the fourth pad that constitute the region are arranged so as to generally form a circular shape in plan view.

21. The optical pickup device according to claim 19, wherein
the regions are provided in the first principal surface and the second principal surface of the circuit board, and
the light source is short-circuited by making a short-circuit in any one of the regions.

22. An optical disc device configured to emit a laser beam to an information recording medium and detect the laser beam reflected by the information recording medium, the optical disc device comprising:
a case; and
the optical pickup device according to claim 11, the optical pickup being movably housed inside the case, wherein
any one of the first short circuit portion and the second short circuit portion of the optical pickup device is exposed to an outside of the case through an opening provided in the case.

23. The optical disc device according to claim 22, further comprising:
a main circuit board which is built in the case and in which a circuit configured to drive the optical pickup device is incorporated; and
a connection board connecting the optical pickup device to the main circuit board, wherein
the first short circuit portion is disposed on an area not overlapping the connection board.
